(19) United States
(12) Patent Application Publication
(10) Pub. No.: US 2019/0394915 A1
(43) Pub. Date: Dec. 26, 2019

(54) ELECTRONIC COMPONENT HOUSING PACKAGE AND ELECTRONIC COMPONENT HOUSING METHOD

(71) Applicant: TDK Corporation, Tokyo (JP)

(72) Inventors: Mitsuhiro TOMIKAWA, Tokyo (JP); Hironori SATO, Tokyo (JP)

(21) Appl. No.: 16/436,161

(22) Filed: Jun. 10, 2019

(30) Foreign Application Priority Data
Jun. 25, 2018 (JP) 2018-119480
Apr. 17, 2019 (JP) 2019-078285

(51) Int. Cl. H05K 13/02; B65D 73/02; H05K 13/04; H05K 13/00; B32B 7/12; C09J 7/20

(52) U.S. Cl. CPC H05K 13/02; B65D 73/02; C09J 7/20; H05K 13/0084; B32B 7/12; H05K 13/0419

(57) ABSTRACT

Disclosed herein is an electronic component housing package that includes a carrier tape having a through hole for housing an electronic component, a base film stuck to the carrier tape and having a lower degree of rigidity than the carrier tape, and a release layer formed on a predetermined area of the base film so as to be exposed to the through hole of the carrier tape.

### BACKGROUND OF THE INVENTION

### Field of the Invention

The present invention relates to an electronic component housing package and, more particularly, to a package for housing an electronic component stuck with an adhesive film such as a die attach film. The present invention also relates to a method of housing such an electronic component in an electronic component housing package.

### Description of Related Art

As described in JP 1998-329866 A and JP 2012-236610 A, an electronic component housing package used in shipping electronic components is generally constituted by a carrier tape in which embossed recesses each housing an electronic component are formed.

In recent years, demands for reduction in thickness of an electronic component such as a thin-film capacitor component or an IC chip have been increasing, and there exists an electronic component having a thickness smaller than 50 μm. Such an ultra-thin type electronic component is not easy to handle at mounting, so that it is sometimes shipped in a state of being stuck with an adhesive film such as a die attach film.

As a method of shipping electronic components stuck with the adhesive film, there is known a method of shipping the electronic components in an on-wafer state. On the other hand, it is difficult to house individualized electronic components in a carrier tape for shipping. That is, when the electronic components stuck with the adhesive film are housed in a normal carrier tape, the adhesive tape ends up sticking with the carrier tape, making it difficult to take out the individual electronic components from the embossed recess. Particularly, when electronic components stuck with the adhesive film are of an ultra-thin type, they may be damaged when being peeled off from the carrier tape.

It can be considered to previously cover the surface of the adhesive film with a release layer so as to prevent the adhesive film and carrier tape from sticking to each other; in this case, however, the electronic component may move inside the embossed recesses, which poses a new problem of occurrence of suction error when the electronic component is taken out using a pickup tool.

### SUMMARY

It is therefore an object of the present invention to provide an electronic component housing package capable of housing therein an electronic component stuck with an adhesive film such as a die attach film. Another object of the present invention is to provide a method of housing such an electronic component in the electronic component housing package.

An electronic component housing package according to one aspect of the present invention includes a carrier tape having a through hole for housing an electronic component, a base film stuck to the carrier tape and having a lower degree of rigidity than the carrier tape, and a release layer formed on a predetermined area of the base film so as to be exposed to the through hole of the carrier tape.

An electronic component housing method according to one aspect of the present invention includes a step of preparing the above-described electronic component housing package, a step of preparing an electronic component stuck with an adhesive film, and a step of housing the electronic component in the through hole such that the adhesive film and the release layer contact each other.

According to the present invention, even when an electronic component stuck with the adhesive film such as a die attach film is housed, it is possible to prevent the adhesive film from sticking to the carrier tape by housing the electronic component in the through hole of the carrier tape such that the adhesive tape and the release layer contact each other. As a result, even when the electronic component having the adhesive film is of an ultra-thin type, the electronic component can be shipped in an individualized state. In addition, the base film supporting the electronic component is lower in rigidity than the carrier tape, so that the electronic component can be pushed up through the base film, making it possible to easily take out the electronic component.

The electronic component housing package according to the present invention may further include an adhesive layer formed on another area different from the predetermined area of the base film so as to stick the carrier tape and the base film. This makes it possible to easily stick the carrier tape and base film together. In this case, the adhesive layer may be provided between the carrier tape and the base film so as not be exposed to the through hole of the carrier tape. This can prevent contact between the adhesive layer and the electronic component.

In the present invention, the through hole may be provided in plural numbers along the longitudinal direction of the carrier tape, and the release layer may be provided continuously along the longitudinal direction of the base film so as to overlap the plurality of through holes. This facilitates the positioning of the release layer on the base film.

An electronic component housing package according to another aspect of the present invention includes a carrier tape having a through hole for housing an electronic component having a release layer, a base film stuck to the carrier tape and having a lower degree of rigidity than the carrier tape, and an adhesive layer formed on a predetermined area of the base film so as to be exposed to the through hole of the carrier tape.

An electronic component housing method according to another aspect of the present invention includes a step of preparing the above-described electronic component housing package, a step of preparing an electronic component having a structure in which a surface of an adhesive film is covered with the release layer, and a step of housing the electronic component in the through hole such that the release layer and the adhesive layer contact each other.

According to the present invention, even when an electronic component having a structure in which the surface of the adhesive film such as a die attach film is covered with the release layer is housed, it is possible to prevent the electronic component from moving inside the through hole of the carrier tape by housing the electronic component in the through hole such that the release layer and the adhesive layer contact each other. This can prevent suction error when the electronic component is taken out of the through hole using a pickup tool or the like. In addition, when the adhesive force between the release layer and the adhesive layer is stronger than that between the release layer and the adhesive film, it is possible to peel off the release layer from the adhesive film by pushing up the electronic component through the base film.

In the present invention, the carrier tape and the base film may be stuck to each other through the same adhesive layer. This eliminates the need to use a plurality of adhesives, making it possible to easily produce the electronic component housing package.

As described above, according to the present invention, it is possible to house the electronic component stuck with the adhesive film such as a die attach film in the electronic component housing package.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic exploded perspective view for explaining the configuration of an electronic component housing package according to a first embodiment of the present invention;

FIG. 2 illustrates an A-A cross section of FIG. 1;

FIG. 3 illustrates a B-B cross section of FIG. 1;

FIG. 4 is a schematic cross-sectional view illustrating an example of an electronic component suitable for being housed in the electronic component housing package according to the first embodiment of the present invention;

FIG. 5 is a schematic view for explaining a method of housing the electronic component in the electronic component housing package according to the first embodiment of the present invention;

FIG. 6 is a schematic view for explaining a method of taking the electronic component out of the electronic component housing package according to the first embodiment of the present invention;

FIG. 7 is a schematic exploded perspective view for explaining the configuration of an electronic component housing package according to a second embodiment of the present invention;

FIG. 8 is a schematic exploded perspective view for explaining the configuration of an electronic component housing package according to a third embodiment of the present invention;

FIG. 9 is a schematic cross-sectional view illustrating the electronic component housing package according to the third embodiment of the present invention;

FIG. 10 is a schematic cross-sectional view illustrating an electronic component according to a modification;

FIG. 11 is a schematic exploded perspective view for explaining the configuration of an electronic component housing package according to a fourth embodiment of the present invention;

FIG. 12 is a schematic cross-sectional view illustrating an example of an electronic component suited to being housed in the electronic component housing package according to the fourth embodiment of the present invention;

FIG. 13 is a schematic view for explaining a method of housing the electronic component in the electronic component housing package according to the fourth embodiment of the present invention;

FIG. 14 is a schematic view for explaining a method of taking the electronic component out of the electronic component housing package according to the fourth embodiment of the present invention;

FIG. 15 is a schematic cross-sectional view illustrating an electronic component according to a modification;

FIG. 16 is a schematic exploded perspective view for explaining the configuration of an electronic component housing package according to a fifth embodiment of the present invention; and

FIG. 17 is a schematic exploded perspective view for explaining the configuration of an electronic component housing package according to a sixth embodiment of the present invention.

### DETAILED DESCRIPTION OF THE EMBODIMENTS

Preferred embodiments of the present invention will be explained below in detail with reference to the accompanying drawings.

### First Embodiment

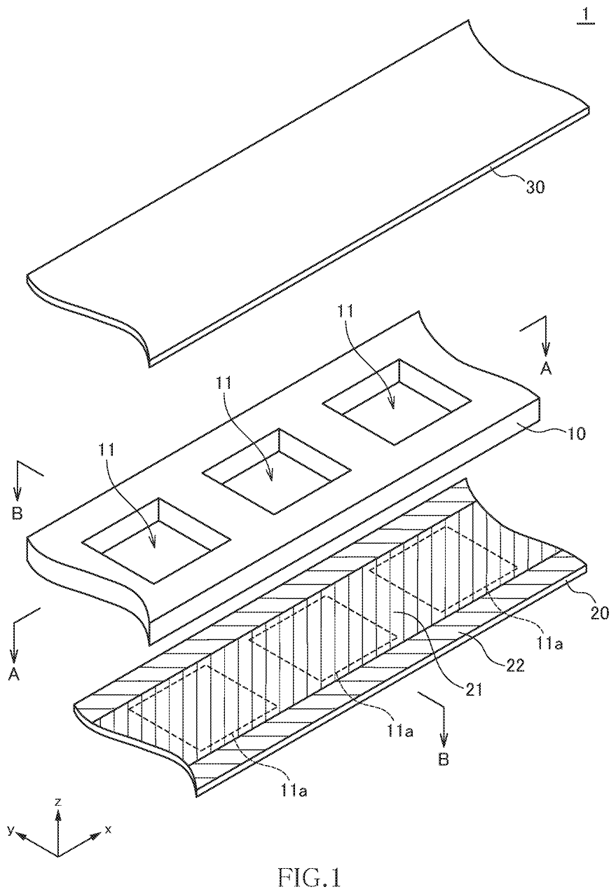

FIG. 1 is a schematic exploded perspective view for explaining the configuration of an electronic component housing package 1 according to the first embodiment of the present invention.

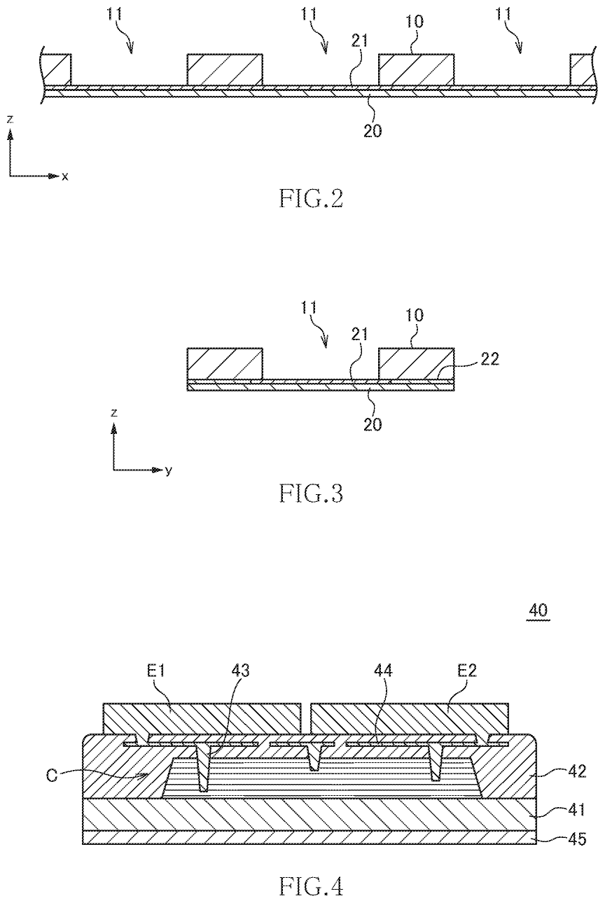

As illustrated in FIG. 1, an electronic component housing package 1 according to the present embodiment includes a carrier tape 10, a base film 20 stuck to one xy surface of the carrier tape 10, and a protective film 30 stuck to the other xy surface of the carrier tape 10. FIGS. 2 and 3 illustrate an A-A cross section and a B-B cross section of FIG. 1. In FIGS. 2 and 3, the protective film 30 is omitted for simplicity.

The carrier tape 10 is a support elongated in the x-direction and has a plurality of through holes 11 arranged in the x-direction so as to be spaced apart from one another at every certain interval. The through hole 11 provides a space for housing an electronic component and is formed penetrating the carrier tape 10 in the z-direction which is the thickness direction thereof. In this point, the structure of the carrier tape 10 differs from an emboss structure of a general carrier tape. The through hole 11 on the base film 20 when the carrier tape 10 and the base film 20 are stuck to each other is positioned at the location denoted by the dashed line 11a shown in FIG. 1.

There is no particular restriction on the material of the carrier tape 10, and resin materials such as polystyrene, polycarbonate, and polyethylene terephthalate can be used, and conductivity is preferably given to such a resin material so as to prevent destruction of the electronic component due to static electricity. The carrier tape 10 functions as the support for the electronic component housing package 1, so that it needs to have a certain thickness for ensuring a predetermined degree of rigidity.

The base film 20 is a tape-like film elongated in the x-direction. There is no particular restriction on the material of the base film 20, and resin materials such as polyethylene terephthalate can be used, and conductivity is preferably given to such a resin material so as to prevent destruction of the electronic component due to static electricity. The thickness of the base film 20 is sufficiently smaller than that of the carrier tape 10, and, at least, the base film 20 needs to be lower in rigidity and more apt to be deformed than the carrier tape 10.

A release layer 21 and an adhesive layer 22 are formed respectively in different areas on the surface of the base film 20. The release layer 21 is made of a material having low surface free energy, such as a silicone compound or fluororesin. At least, the release layer 21 needs to be made of a material having lower adhesive force with respect to the electronic component than the base film 20. As denoted by the reference numeral 11a , when the carrier tape 10 and the base film 20 are stuck to each other, the release layer 21 is exposed through the through holes 11. In the present embodiment, the release layer 21 is provided continuously along the longitudinal direction of the base film 20 so as to overlap the plurality of through holes 11. This eliminates the need to position the release layer 21 in the x-direction when the release layer 21 is provided on the base film 20. Further, the width of the release layer 21 in the y-direction is larger than the width of each through hole 11 in the y-direction, whereby a part of the release layer 21 that is exposed through the through hole 11 is completely covered with the release layer 21.

The adhesive layer 22 is a member for sticking the carrier tape 10 and the base film 20 and extends in the x-direction along the end portions of the base film 20 in the y-direction. In the present embodiment, a part of the base film 20 overlapping the through holes 11 is completely covered with the release layer 21, so that even when the carrier tape 10 and the base film 20 are stuck to each other, the adhesive layer 22 is not exposed to the through holes 11.

The protective film 30 is a film for closing the through holes 11 and is stuck to the carrier tape 10 using an adhesive after the electronic components are housed in the respective through holes 11.

FIG. 4 is a schematic cross-sectional view illustrating an example of an electronic component 40 suitable for being housed in the electronic component housing package 1 according to the present embodiment.

The electronic component 40 illustrated in FIG. 4 is an ultra-thin type thin film capacitor and includes a support 41, a capacitor layer C formed on a surface of the support 41 and constituted of a plurality of conductive layers and a plurality of insulating layers which are alternately laminated, and a resin layer 42 burying the capacitor layer C therein. Among the plurality of conductive layers constituting the capacitor layer C, even-numbered conductive layers are connected to a terminal electrode E1 through a through hole conductor 43 and a rewiring layer 44, and odd-numbered conductive layers are connected to a terminal electrode E2 through the through hole conductor 43 and rewiring layer 44. The terminal electrodes E1 and E2 are formed on the upper surface of the electronic component 40. The lower surface of the electronic component 40 is covered with a die attach film 45 which is an adhesive film.

The thickness of the electronic component 40 is smaller than 50 μm, e.g., about 30 μm. Thus, it is difficult to stick the die attach film 45 to the electronic component 40 after individualization. This implies that it is necessary to stick the die attach film 45 to the electronic component 40 in an on-wafer state and then to individualize the wafer in this state. As described above, it is difficult to stick the die attach film 45 to the individualized electronic component 40 after shipping and, thus, it is necessary to ship the electronic component 40 in a state of being stuck with the die attach film 45. The electronic component housing package 1 according to the present embodiment can be used for such a purpose.

FIG. 5 is a schematic view for explaining a method of housing the electronic component 40 in the electronic component housing package 1. First, the carrier tape 10 in which the through holes 11 are formed and the base film 20 on which the release layer 21 and adhesive layer 22 are formed are prepared and stuck to each other through the adhesive layer 22. As a result, the release layer 21 is exposed to the through holes 11. Subsequently, the electronic component 40 is housed inside each through hole 11 such that the die attach film 45 and the release layer 21 contact each other. As described above, the release layer 21 is made of a material having low surface free energy, such as a silicone compound or fluororesin, so that even when the die attach film 45 and the release layer 21 contact each other, adhesion strength therebetween can be kept low. Then, the protective film 30 is stuck to the carrier tape 10 so as to close the through holes 11, whereby the packaging of the electronic components 40 is completed.

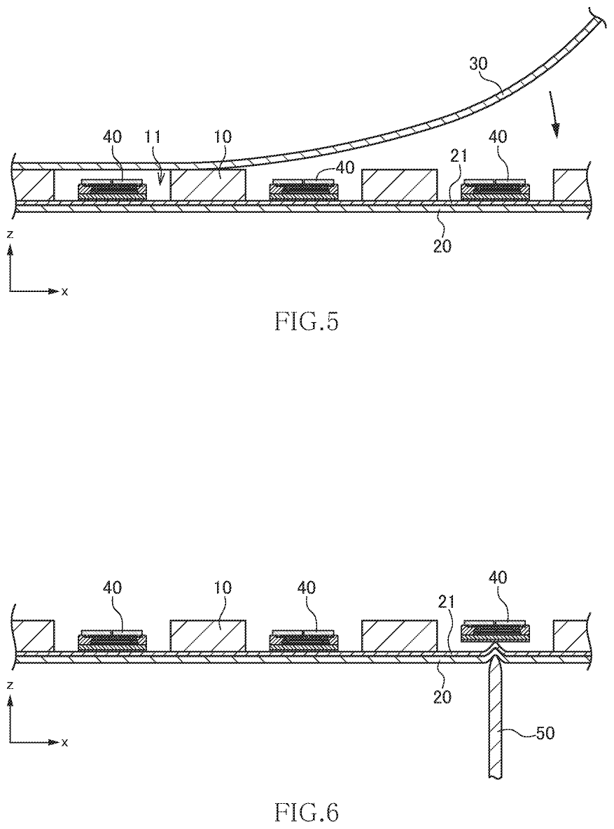

FIG. 6 is a schematic view for explaining a method of taking the electronic component 40 out of the electronic component housing package 1. When the electronic component 40 is taken out of the electronic component housing package 1, the protective film 30 is peeled off first. Then, a pushing pin 50 is used to push up the electronic component 40 from the lower surface side through the base film 20. As described above, the base film 20 is low in rigidity, so that when the base film 20 is pushed up with the pushing pin 50, it is easily deflected, and the die attach film 45 and the release layer 21 contact each other only at a portion pushed with the pushing pin 50. As a result, the adhesive force between the die attach film 45 and the release layer 21 is further reduced, making it possible to easily take the electronic component 40 out of the through hole 11 by using a not-shown pickup tool.

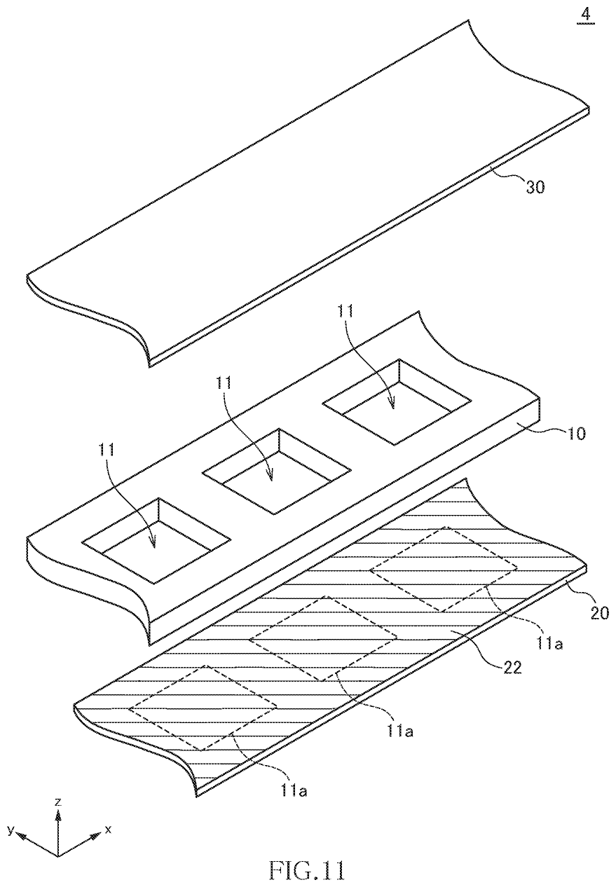

As described above, the electronic component housing package 1 according to the present embodiment includes the carrier tape 10 high in rigidity, the base film 20 low in rigidity, and the release layer 21 formed on a surface of the base film 20, so that even when the electronic component 40 having the die attach film 45 is housed, it can be easily taken out. While the electronic component 40 illustrated in FIG. 4 has the die attach film 45 on the lower surface side thereof, it may have an anisotropic conductive film 46 which is an adhesive film on the upper surface side at which the terminal electrodes E1 and E2 are provided, like an electronic component 40A illustrated in FIG. 10. In this case, the electronic component may be housed in the electronic component housing package 1 such that the anisotropic conductive film 46 having adhesiveness and the release layer 21 contact each other.

### Second Embodiment

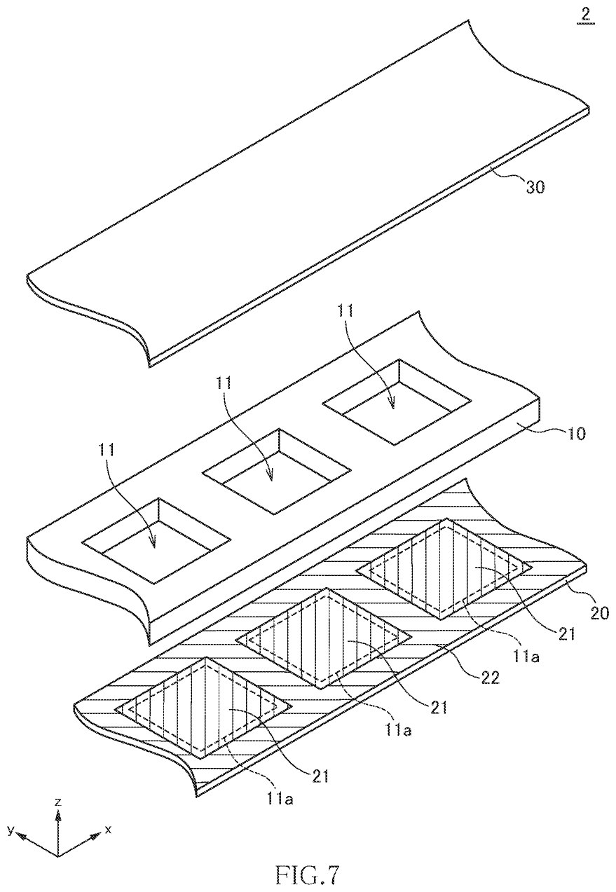

FIG. 7 is a schematic exploded perspective view for explaining the configuration of an electronic component housing package 2 according to the second embodiment of the present invention.

As illustrated in FIG. 7, in the electronic component housing package 2 according to the present embodiment, the release layer 21 is not formed continuously, but a plurality of release layers 21 are formed intermittently in the x-direction each at a portion overlapping the though hole 11 with a slight margin therearound. In this point, the electronic component housing package 2 according to the present embodiment differs from the electronic component housing package 1 according to the first embodiment, and other configurations are the same as those of the electronic component housing package 1 according to the first embodiment, so the same reference numerals are given to the same elements, and overlapping description will be omitted.

As exemplified in the present embodiment, the release layer 21 may not be formed continuously in the x-direction in the present invention, and the plurality of release layers 21 may be arranged intermittently.

### Third Embodiment

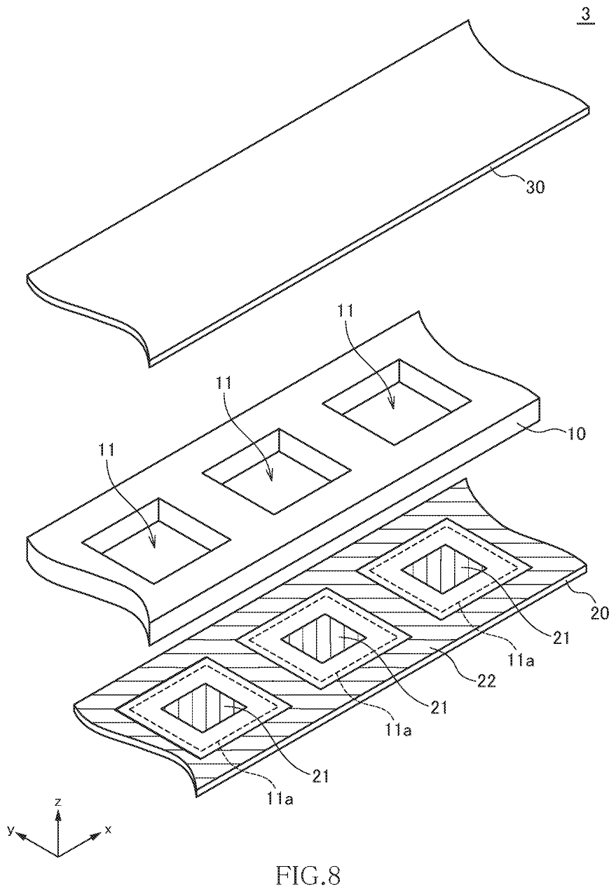

FIG. 8 is a schematic exploded perspective view for explaining the configuration of an electronic component housing package 3 according to the third embodiment of the present invention.

As illustrated in FIG. 8, the electronic component housing package 3 according to the third embodiment differs from the electronic component housing package 2 according to the second embodiment in that the release layer 21 is formed only at the center of a portion overlapping the through hole 11. Other configurations are the same as those of the electronic component housing package 2 according to the second embodiment, so the same reference numerals are given to the same elements, and overlapping description will be omitted.

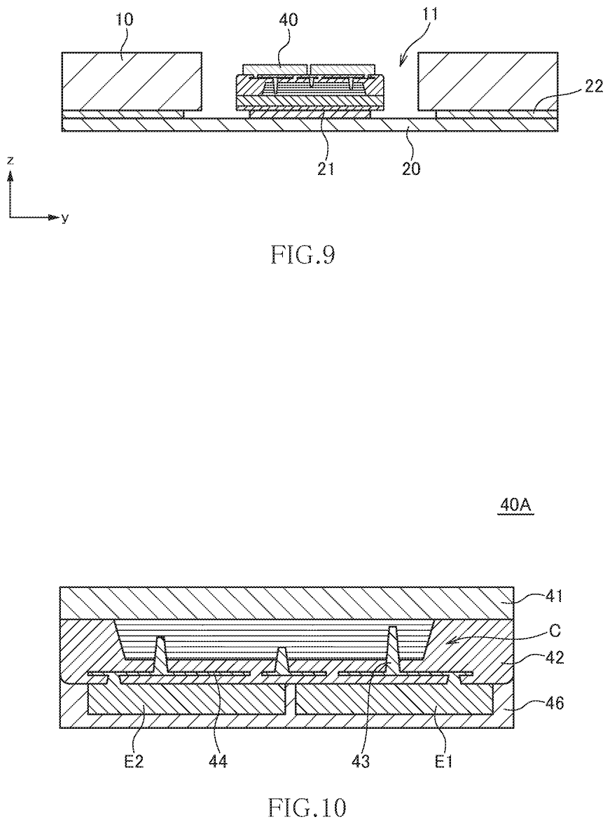

As exemplified in the present embodiment, a portion overlapping the through hole 11 may not be completely covered with the release layer 21, and it is sufficient that the release layer 21 is provided at a portion contacting at least the electronic component 40 or 40A. In this case, as illustrated in FIG. 9 which is a cross-sectional view, the area of the release layer 21 may be smaller than that of the electronic component 40 or 40A unless the electronic component 40 or 40A and the base film 20 directly contact each other.

### Fourth Embodiment

FIG. 11 is a schematic exploded perspective view for explaining the configuration of an electronic component housing package 4 according to the fourth embodiment of the present invention.

As illustrated in FIG. 11, the electronic component housing package 4 according to the fourth embodiment differs from the electronic component housing package 1 according to the first embodiment in that the adhesive layer 22 is provided on the entire surface of the base film 20. Accordingly, the release layer 21 is not provided on the base film 20. Other configurations are the same as those of the electronic component housing package 1 according to the first embodiment, so the same reference numerals are given to the same elements, and overlapping description will be omitted.

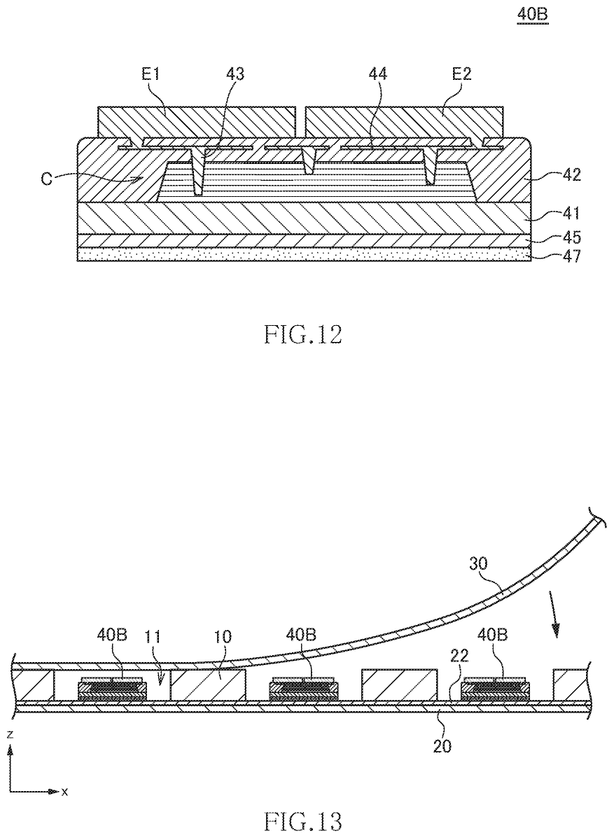

FIG. 12 is a schematic cross-sectional view illustrating an example of an electronic component 40B suited to being housed in the electronic component housing package 4 according to the present embodiment.

The electronic component 40B illustrated in FIG. 12 differs from the electronic component 40 illustrated in FIG. 4 in that the surface of the die attach film 45 is covered with a release layer 47. Other configurations are the same as those of the electronic component 40 illustrated in FIG. 4, so the same reference numerals are given to the same elements, and overlapping description will be omitted.

The release layer 47 is a cover film made of a material having low surface free energy, such as a silicone compound or fluororesin, so that even when the die attach film 45 and the release layer 47 contact each other, adhesion therebetween can be kept low.

FIG. 13 is a schematic view for explaining a method of housing the electronic component 40B in the electronic component housing package 4. First, the carrier tape 10 in which the through holes 11 are formed and the base film 20 on which the adhesive layer 22 is formed are prepared and stuck to each other through the adhesive layer 22. As a result, the adhesive layer 22 is exposed to the through holes 11. Subsequently, the electronic component 40B is housed inside each through hole 11 such that the release layer 47 and the adhesive layer 22 contact each other. Although the release layer 47 is made of a material having low surface free energy, such as a silicone compound or fluororesin as described above, the adhesive layer 22 is exposed to the through hole 11, so that the electronic component 40B is immobilized in the mounted position inside the through hole 11. The materials of the release layer 47 and adhesive layer 22 are selected such that the adhesive force between the release layer 47 and the adhesive layer 22 is stronger than that between the release layer 47 and the die attach film 45. Then, the protective film 30 is stuck to the carrier tape 10 so as to close the through holes 11, whereby the packaging of the electronic components 40B is completed.

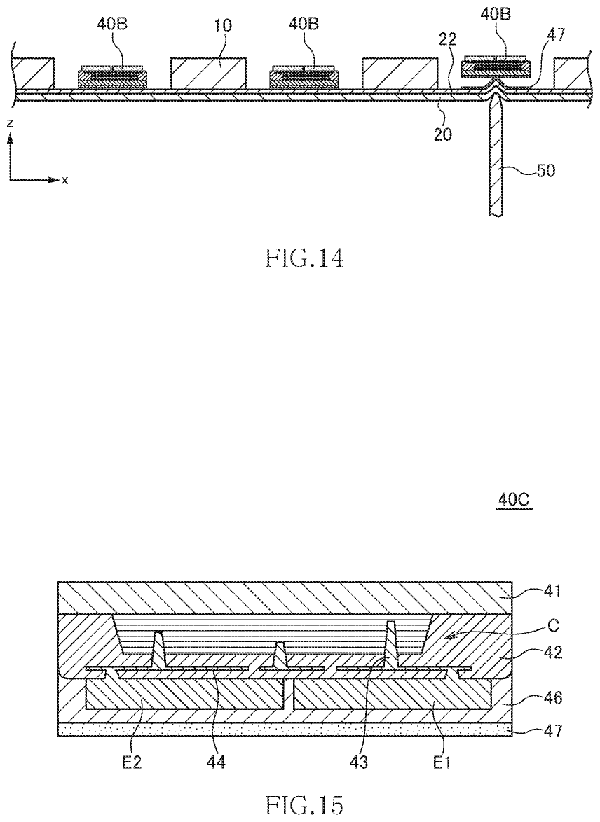

FIG. 14 is a schematic view for explaining a method of taking the electronic component 40B out of the electronic component housing package 4. When the electronic component 40B is taken out of the electronic component housing package 4, the protective film 30 is peeled off first. Then, the pushing pin 50 is used to push up the electronic component 40B from the lower surface side through the base film 20. As described above, the base film 20 is low in rigidity, so that when the base film 20 is pushed up with the pushing pin 50, it is easily deflected. Since the adhesive force between the release layer 47 and the adhesive layer 22 is stronger than that between the release layer 47 and the die attach film 45, the release layer 47 comes off the die attach film 45 and remains on the adhesive layer side, making it possible to easily take the electronic component 40B out of the through hole 11 by using a not-shown pickup tool.

As described above, in the electronic component housing package 4 according to the present embodiment, the adhesive layer 22 is exposed to the through hole 11, so that the electronic component 40B whose surface is covered with the release layer 47 can be fixed inside the through hole 11. This allows the electronic component 40B to be reliably taken out using the pickup tool or the like. In addition, since the adhesive force between the release layer 47 and the adhesive layer 22 is stronger than that between the release layer 47 and the die attach film 45, the release layer 47 spontaneously peels off from the die attach film 45 by push-up of the pushing pin 50. Thus, a specific process for peeling off the release layer 47 is not necessary.

Although the electronic component 40B illustrated in FIG. 12 has the die attach film 45 and the release layer 47 on the lower surface side thereof, it may have an anisotropic conductive film 46 and the release layer 47 on the upper surface side at which the terminal electrodes E1 and E2 are provided, like an electronic component 40C illustrated in FIG. 15. In this case, the electronic component may be housed in the electronic component housing package 4 such that the release layer 47 and the adhesive layer 22 contact each other.

### Fifth Embodiment

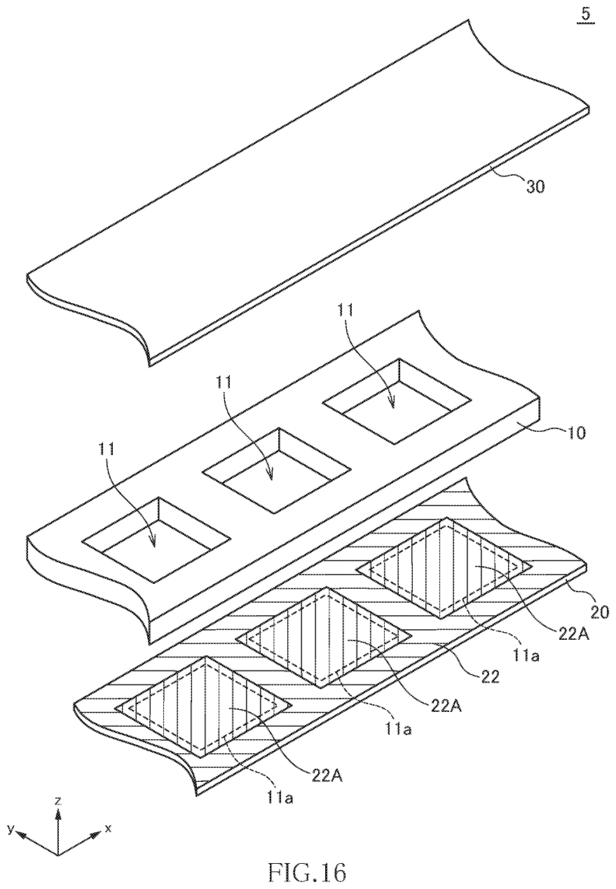

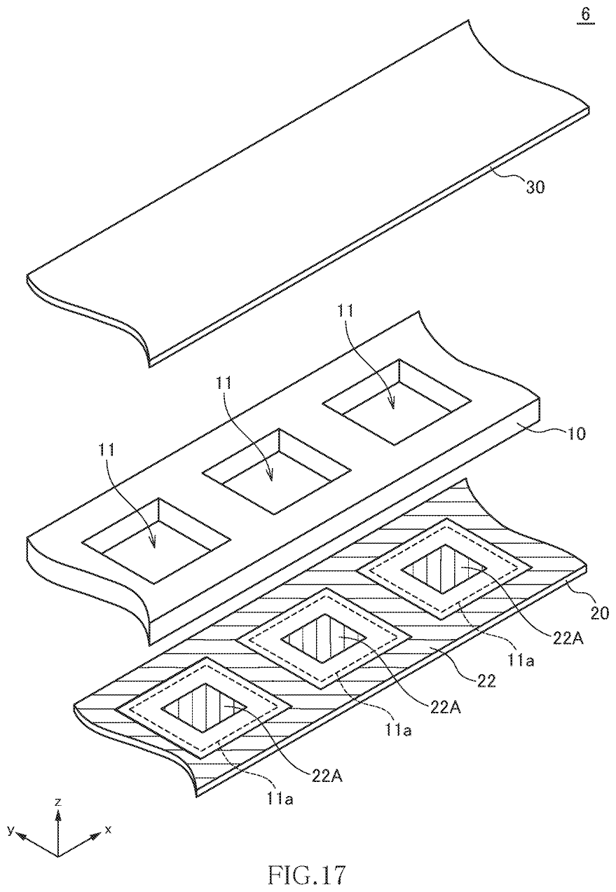

FIG. 16 is a schematic exploded perspective view for explaining the configuration of an electronic component housing package 5 according to the fifth embodiment of the present invention.

As illustrated in FIG. 16, the electronic component housing package 5 according to the fifth embodiment differs from the electronic component housing package 4 according to the fourth embodiment in that the adhesive layer 22 that sticks the base film 20 and carrier tape 10 and an adhesive layer 22A provided at a portion overlapping the through hole 11 are made of mutually different adhesive materials. Other configurations are the same as those of the electronic component housing package 4 according to the fourth embodiment, so the same reference numerals are given to the same elements, and overlapping description will be omitted.

As exemplified in the present embodiment, the adhesive layer 22 that sticks the base film 20 and carrier tape 10 and the adhesive layer 22A provided at a portion overlapping the through hole 11 need not be made of the same adhesive material, and mutually different adhesive materials may be selected for the adhesive layers 22 and 22A according to characteristics required thereof.

### Sixth Embodiment

FIG. 17 is a schematic exploded perspective view for explaining the configuration of an electronic component housing package 6 according to the sixth embodiment of the present invention.

As illustrated in FIG. 17, the electronic component housing package 6 according to the sixth embodiment differs from the electronic component housing package 5 according to the fifth embodiment in that the adhesive layer 22A is formed only at the center of a portion overlapping the through hole 11. Other configurations are the same as those of the electronic component housing package 5 according to the fifth embodiment, so the same reference numerals are given to the same elements, and overlapping description will be omitted.

As exemplified in the present embodiment, a portion overlapping the through hole 11 need not be completely covered with the adhesive layer 22 or 22A, and it is sufficient that the adhesive layer 22 or 22A is provided at a portion contacting at least the electronic component 40B or 40C. In this case, the area of the adhesive layer 22 or 22A may be smaller than that of the electronic component 40B or 40C.

It is apparent that the present invention is not limited to the above embodiments, but may be modified and changed without departing from the scope and spirit of the invention.

What is claimed is:

1. An electronic component housing package comprising:
a carrier tape having a through hole for housing an electronic component;
a base film stuck to the carrier tape and having a lower degree of rigidity than the carrier tape; and
a release layer formed on a predetermined area of the base film so as to be exposed to the through hole of the carrier tape.

2. The electronic component housing package as claimed in claim 1, further comprising an adhesive layer formed on another area different from the predetermined area of the base film so as to stick the carrier tape and the base film.

3. The electronic component housing package as claimed in claim 2, wherein the adhesive layer is provided between the carrier tape and the base film so as not be exposed to the through hole of the carrier tape.

4. The electronic component housing package as claimed in claim 1,
wherein the through hole is provided in plural numbers along a longitudinal direction of the carrier tape, and
wherein the release layer is provided continuously along the longitudinal direction of the base film so as to overlap the plurality of through holes.

5. An electronic component housing method comprising:
preparing an electronic component housing package, comprising:
a carrier tape having a through hole for housing an electronic component;
a base film stuck to the carrier tape and having a lower degree of rigidity than the carrier tape; and
a release layer formed on a predetermined area of the base film so as to be exposed to the through hole of the carrier tape;
preparing an electronic component stuck with an adhesive film; and
housing the electronic component in the through hole such that the adhesive film and the release layer contact each other.

6. An electronic component housing package comprising:
a carrier tape having a through hole for housing an electronic component having a release layer;
a base film stuck to the carrier tape and having a lower degree of rigidity than the carrier tape; and
an adhesive layer formed on a predetermined area of the base film so as to be exposed to the through hole of the carrier tape.

7. The electronic component housing package as claimed in claim 6, wherein the carrier tape and the base film are stuck to each other through the adhesive layer.

8. An electronic component housing method comprising:
preparing an electronic component housing package, comprising:
a carrier tape having a through hole for housing an electronic component having a release layer;
a base film stuck to the carrier tape and having a lower degree of rigidity than the carrier tape; and
an adhesive layer formed on a predetermined area of the base film so as to be exposed to the through hole of the carrier tape;
preparing an electronic component having a structure in which a surface of an adhesive film is covered with the release layer; and
housing the electronic component in the through hole such that the release layer and the adhesive layer contact each other.

9. The electronic component housing method as claimed in claim 8, wherein an adhesive force between the release layer and the adhesive layer is stronger than that between the release layer and the adhesive film.
